(19) United States
(12) Patent Application Publication
(10) Pub. No.: US 2004/0201014 A1
(43) Pub. Date: Oct. 14, 2004

(54) Composition for forming porous film, porous film and method for forming the same, interlevel insulator film, and semiconductor device

(75) Inventors: Fujio Yagihashi, Niigata-ken (JP); Motoaki Iwabuchi, Niigata-ken (JP); Takeshi Asano, Niigata-ken (JP); Hideo Nakagawa, Oumihachiman-shi (JP); Masaru Sasago, Osaka (JP)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Matsushita Electric Industrial Co., Ltd.

(21) Appl. No.: 10/819,581

(22) Filed: Apr. 7, 2004

(30) Foreign Application Priority Data
Apr. 9, 2003 (JP) 2003-104773

(51) Int. Cl. H01L 35/24

(52) U.S. Cl. 257/40

(57) ABSTRACT

Provided are a coating liquid for forming porous film which can produce desirably controlled thickness of the film and which excels in stability, and a semiconductor device comprising the porous film inside. More specifically the invention provides a composition for forming porous film comprising a solution comprising a polymer obtainable by hydrolysis and condensation of a reaction solution in the presence of basic substance as catalyst wherein the reaction solution has been produced by hydrolysis and condensation, in the presence of acidic substance as catalyst, of one or more silane compounds selected from the group consisting of the compounds represented by Formulae (1) and (2):

(R)ₐSi(OR¹)₄₋ₐ (1)

(R²O)_{b}(R³)_{4-b}Si—R⁴—Si(OR⁵)c(R⁶)_{4-c} (2)

The composition preferably comprise an organic solvent.

### CROSS-REFERENCE TO RELATED APPLICATION

The present application claims priority to Japanese Patent Application No. 2003-104773, filed Apr. 9, 2003, the disclosure of which is incorporated herein by reference in its entirely.

### BACKGROUND OF THE INVENTION

1. Field of the Invention

The present invention relates to a composition for film formation, which can be formed into a porous film that excels in dielectric properties, adhesion, film consistency and mechanical strength, and has reduced absorption; a porous film and a method for forming the same; and a semiconductor device, which contains the porous film inside.

2. Description of the Related Art

In the fabrication of semiconductor integrated circuits, as the circuits are packed tighter, an increase in interconnection capacitance, which is a parasitic capacitance between metal interconnections, leads to an increase in interconnection delay time, thereby hindering the enhancement of the performance of semiconductor circuits. The interconnection delay time is called an RC delay, which is in proportion to the product of the electric resistance of the metal interconnections and the static capacitance between the interconnections. Reducing the interconnection delay time requires reducing the resistance of metal interconnections or the interconnection capacitance.

The reduction in resistance of the interconnection metal and the interconnection capacitance can prevent a densely packed semiconductor device from causing an interconnection delay, thereby realizing a smaller and faster semiconductor device with reduced power consumption.

In an attempt to reduce the resistance of metal interconnections, in recent years, metallic copper interconnections have been employed more than conventional aluminum interconnections in the structure of a device. However, use of this structure all has limits in the enhancement of the performance, so the reduction in interconnection capacitance is an urgent necessity for higher performance of semiconductors.

One method for reducing interconnection capacitance is to reduce the relative permittivity (dielectric constant) of an interlevel insulator film disposed between metal interconnections. As such an insulator film with a low relative permittivity, it has been considered to use a porous film instead of a silicon oxide film, which has been used conventionally. A porous film can be said to be the only practical film as a material with a relative permittivity of 2.0 or less, and various methods for forming a porous film have been proposed

A first method for forming a porous film is as follows: a precursor solution of a siloxane polymer containing a thermally unstable organic component is synthesized; then the precursor solution is applied on the substrate to form a coating film; and later, a heat treatment is applied to decompose and volatilize the organic component. The result is a number of micro-pores formed in the film.

As a second method for forming a porous film, it is well known to carry out processing as follows: a silica sol solution is applied onto a substrate by coating or using a CVD method so as to form a wet gel; and then the silica sol is subjected to a condensation reaction while restricting volume reduction by controlling the speed of the evaporation of the solvent from the wet gel.

As a third method for forming a porous film, it is well known that a silica micro-particle solution is applied on a substrate to form a coating film, and then the coating film is sintered to form a number of micro-pores between silica micro-particles.

As a fourth method, Japanese Patent Provisional Publication No. 2000-44875 proposes a composition for porous film formation, which is characterized by containing a compound having (A) a component expressed by (R⁹)ₘSi(OR¹⁰)₄₋ₘ (R⁹ and R¹⁰ are univalent organic radicals, and m is an integer of 0 to 2); (B) a metal chelate compound; and (C) a compound having a polyalkylene oxide structure.

However, these methods have respective major drawbacks as follows.

In the first method for forming a porous film, the synthesis of the precursor solution of the siloxane polymer increases the cost. In addition, the formation of the coating film by coating the precursor solution increases the amount of silanol groups remaining in the coating film, which causes a degassing phenomenon indicating the evaporation of water and the like in the heat treatment process that is conducted later and, which also deteriorates the film quality due to the porous film absorbing humidity.

In the second method for forming a porous film, the speed control of the evaporation of the solvent from the wet gel requires a special type of coating device, which increases the cost. In addition, a significant amount of silanol remains on the surface of the micro-pores, which must be silanized because otherwise hygroscopicity is high and the film quality decreases. The silanization makes the process more complicated. In the case where a wet gel is formed by the CVD process, it is necessary to use a special type of CVD device, which is different from the plasma CVD device generally used in the semiconductor process, thereby also increasing the cost.

In the third method for forming a porous film, the diameter of the micro-pores formed between the silica micro-particles, which is determined by the accumulation structure of the silica micro-particles that are accumulated geometrically, becomes very large. This makes it difficult to set the relative permittivity of the porous film to 2 or below.

In the case of the fourth method, out of the three components (A), (B), and (C), the metal chelate compound of (B) is essential to increase the compatibility of the components (A) and (C), and to make the thickness of the coating film uniform after being hardened. However, it is not preferable because it makes the manufacturing process complicated and increases the cost. Therefore, it is desired to develop a material, which enables a homogeneous solution to be formed without a chelate component and the coating film to be flat after being hardened.

Contrary to the conventional method forming porous film, it has recently become known that a silicone resin produced by hydrolysis and condensation of a silicone resin in the presence of a basic catalyst instead of a acidic catalyst is coated and sintered to form porous film having low dielectric constant.

However, there is a problem that although the film formed by the silicone resin has high mechanical strength when it has relatively high dielectric constant, the mechanical strength is lowered as the dielectric constant is lowered. Thus, the film is unsuitable for producing an actual semiconductor device.

As mentioned above, the conventional materials have problems such as deterioration of film quality during the heat treatment step and high cost. Moreover, since the pore diameters enlarge during formation of porous film, it is difficult to obtain low dielectric constant. Further, when the conventional porous film is incorporated into the multi-level interconnects of the semiconductor device as an insulator film, the mechanical strength necessary for producing the semiconductor device is not obtained.

Thus, when the dielectric constant of the porous film used as an insulator film in the multi-level interconnects of the semiconductor device is too high, the RC delay in the multi-level interconnects of the semiconductor device is increased. Consequently, the performance of the semiconductor device (high speed and low power consumption) has not been improved. Furthermore, a porous film having low mechanical strength lowers the reliability of the semiconductor device.

### SUMMARY OF THE INVENTION

Taking the above problems into consideration, the object of the invention is to provide a coating liquid which can easily form porous film having a desirably controlled thickness and having high mechanical strength. The coating liquid excels in stability. Moreover, the object of the invention is to provide a high-performing and highly reliable semiconductor device comprising the porous film inside.

The inventors focused intently on the development of a coating liquid for forming the porous film. As a result, they found the composition for forming porous film having low dielectric constant as well as high mechanical strength and being applicable to the semiconductor production process, and the method for forming the porous film. Then, they completed the invention.

According to the invention, provided are a composition for forming porous film comprising a solution comprising a polymer obtainable by hydrolysis and condensation of a reaction solution in the presence of basic substance as catalyst wherein the reaction solution has been produced by hydrolysis and condensation, in the presence of acidic substance as catalyst, of one or more silane compounds selected from the group consisting of the compounds represented by Formulae (1) and (2):

(R)ₐSi(OR¹)₄₋ₐ (1)

(R²O)_{b}(R³)_{4-b}Si—R⁴—Si(OR⁵)c(R⁶)_{4-c} (2),

and porous film and an insulator film which are obtainable by the composition for forming porous film.

In Formula (1), R represents a straight-chain (linear) or branched alkyl group having 1 to 8 carbons or an aryl group which each group may have a substituent, and when two or more Rs are present, the Rs may be independently identical or different; R¹ represents an alkyl group having 1 to 4 carbons, and when two or more R¹s are present, the R¹s may be independently identical or different; a represents an integer of 0 to 3.

In Formula (2), R² and R⁵ each independently represents an alkyl group having 1 to 4 carbons; R³ and R⁶ each independently represents a straight-chain or branched alkyl group having 1 to 8 carbons or the aryl group; b and c each represents an integer of 0 to 3; R⁴ independently represents an oxygen atom, a phenylene group, —(CH₂)_{d}— (wherein d is a integer of 1 to 6) or —{Si(R⁷) (R⁸)O}ₑ— (wherein R⁷ and R⁸ each represents an alkyl group having 1 to 6 carbons or an aryl group); e is an integer of 1 to 20.

The semiconductor device of the invention comprises internal porous film which is formable by a composition for forming porous film comprising a solution comprising a polymer obtainable by hydrolysis and condensation of a reaction solution in the presence of basic substance as catalyst wherein the reaction solution has been produced by hydrolysis and condensation, in the presence of acidic substance as catalyst, of one or more silane compounds selected from the group consisting of the compounds represented by Formulae (1) and (2):

(R)ₐSi(OR¹)₄₋ₐ (1)

(R²O)_{b}(R³)_{4-b}Si—R⁴—Si (OR⁵)c(R⁶)_{4-c} (2)

wherein, in Formula (1), R represents a straight-chain or branched alkyl group having 1 to 8 carbons or an aryl group which each group may have a substituent, and when two or more Rs are present, the Rs may be independently identical or different; R¹ represents an alkyl group having 1 to 4 carbons, and when two or more R¹s are present, the R¹s may be independently identical or different; a represents an integer of 0 to 3; and in Formula (2), R² and R⁵ each independently represents an alkyl group having 1 to 4 carbons; R³ and R⁶ each independently represents a straight-chain or branched alkyl group having 1 to 8 carbons or the aryl group; b and c each represents an integer of 0 to 3; R⁴ independently represents an oxygen atom, a phenylene group, —(CH₂)_{d}— (wherein d is a integer of 1 to 6) or —{Si(R⁷) (R⁸)O}ₑ— (wherein R⁷ and R⁸ each represents an alkyl group having 1 to 6 carbons or an aryl group); e is an integer of 1 to 20. More specifically, said porous film is used as insulator film of multi-level in the semiconductor device.

According to the invention, the mechanical strength of the semiconductor device is secured, while the hygroscopic property of the porous film is decreased. Thus, the semiconductor device containing an internal insulator film having low dielectric constant is obtained. Because of lower dielectric constant of the insulator film, the parasitic capacitance of the area around the multi-level interconnects is decreased, leading to the high-speed operation and low power consumption of the semiconductor device.

Moreover, it is preferable in the semiconductor device of the invention that said porous film is between metal interconnections in a same layer of multi-level interconnects, or is between upper and lower metal interconnection layers. This arrangement can achieve a high-performing and highly reliable semiconductor device.

The use of the composition for forming porous film of the invention facilitates the formation of porous film having a desirably controlled thickness and excellent stability. This porous film has a low dielectric constant and excels in adhesion, film uniformity and mechanical strength. In addition, use of the porous film formable by the composition of the invention as the insulator film of the multi-level interconnects can achieve a high-performing and highly reliable semiconductor device.

### BRIEF DESCRIPTION OF THE DRAWING

FIG. 1 is a schematic cross-sectional view of a semiconductor device of the invention.

### DETAILED DESCRIPTION OF THE PREFERRED EMBODIMENTS

The silane compound used in the invention is a compound represented by Formula (1), wherein R represents a straight-chain or branched alkyl group having 1 to 8 carbons or an aryl group, and R may have a substituent. The silane compound may include a methyl group, ethyl group, propyl group, isopropyl group, butyl group, isobutyl group, sec-butyl group, tert-butyl group, pentyl group, sec-pentyl group, neopentyl group, hexyl group, 2-ethylhexyl group, heptyl group, octyl group, phenyl group, o-tolyl group, m-tolyl group, p-tolyl group, xylyl group, and benzyl group.

In General Formula (1), R¹ is an alkyl group having 1 to 4 carbons and may include a methyl group, ethyl group, propyl group, isopropyl group and butyl group. In General Formula (1), a is an integer of 0 to 3.

The silane compound represented by the Formula (1) may include, but is not limited to, tetramethoxysilane, tetraethoxysilane, tetrapropoxysilane, tetrabutoxysilane, methyltrimethoxysilane, methyltriethoxysilane, methyltripropoxysilane, ethyltrimethoxysilane, propyltrimethoxysilane, butyltrimethoxysilane, pentyltrimethoxysilane, hexyltrimethoxysilane, 2-ethylhexyltrimethoxysilane, phenyltrimethoxysilane, dimethyldimethoxysilane, dimethyldiethoxysilane, trimethylmethoxysilane, triethylmethoxysilane and butyldimethylmethoxysilane.

The silane compound represented by the Formula (2) may include bis(trimethoxysilyl)methane, bis(triethoxysilyl)methane, bis(methyldimethoxysilyl)methane, bis(methyldiethoxysilyl)methane, bis(dimethoxysilyl)methane, bis(diethoxysilyl)methane, bis(dimethylsilyl)methane, bis(dimethylmethoxysilyl)methane, bis(dimethylethoxysilyl)methane, bis-1,2-(trimethoxysilyl)ethane, bis-1,2-(triethoxysilyl)ethane, bis-1,2-(methyldimethoxysilyl)ethane, bis-1,2-(methyldiethoxysilyl)ethane, bis-1,2-(methylmethoxysilyl)ethane, bis-1,2-(methylethoxysilyl)ethane, bis-1,2-(dimethoxysilyl)ethane, bis-1,2-(diethoxysilyl)ethane, bis-1,2-(dimethylsilyl)ethane, bis-1,2-(dimethylmethoxysilyl)ethane, bis-1,2-(dimethylethoxysilyl)ethane, bis-1,6-(trimethoxysilyl)hexane, bis-1,6-(triethoxysilyl)hexane, bis-1,6-(methyldimethoxysilyl)hexane, bis-1,6-(methyldiethoxysilyl)hexane, bis-1,6-(methylmethoxysilyl)hexane, bis-1,6-(methylethoxysilyl)hexane, bis-1,6-(dimethoxysilyl)hexane, bis-1,6-(diethoxysilyl)hexane, bis-1,6-(dimethylsilyl)hexane, bis-1,6-(dimethylmethoxysilyl)hexane, bis-1,6-(dimethylethoxysilyl)hexane, bis-1,4-(trimethoxysilyl)benzene, bis-1,4-(triethoxysilyl)benzene, bis-1,4-(methyldimethoxysilyl)benzene, bis-1,4-(methyldiethoxysilyl)benzene, bis-1,4-(methylmethoxysilyl)benzene, bis-1,4-(methylethoxysilyl)benzene, bis-1,4-(dimethoxysilyl)benzene, bis-1,4-(diethoxysilyl)benzene, bis-1,4-(dimethylsilyl)benzene, bis-1,4-(dimethylmethoxysilyl)benzene and bis-1,4-(dimethylethoxysilyl)benzene.

The silane compound turns into a polymer solution during hydrolysis and condensation in the presence of an acidic substance as catalyst. The acid used may include inorganic acid such as hydrochloric acid, sulfuric acid and nitric acid; sulfonic acid such as methanesulfonic acid, benzenesulfonic acid, p-toluenesulfonic acid and trifluoromethane sulfonic acid; organic acid such as formic acid, acetic acid, propionic acid, oxalic acid, malonic acid, fumaric acid, maleic acid, tartaric acid, citric acid and malic acid; and phosphoric acid.

The acid substance may preferably contain an acidic functional group which can be dissociated in solvent to generate a proton toward the polymer undissloved in the solvent used. It is because such acid substance can be easily removed by filtration of the catalyst at the end of the reaction without damaging the subsequent reaction. The acidic functional group which can generate a proton may be a sulfo group (—SO₃H) or a carboxyl group (—COOH). The example may include, but not limited to, a cation exchange resin which has polystyrene skelton with a substituent containing the acidic functional group.

The acidic substance can be used singly or as admixture of two or more thereof. The acidic substance may be added in an amount of preferably 0.0001 to 0.2 mole, more preferably 0.001 to 0.05 mole equivalent to that of silane compound.

Moreover, an amount of the water for hydrolysis may be preferably 0.5 to 10, more preferably 1.0 to 4.0 times the number of moles necessary to hydrolyze the silane compound completely.

The prepared polymer solution is further polymerized in the presence of a basic substance as catalyst. The basic substance may include ammonia, amine such as methylamine, ethylamine, propylamine, diisopropylamine, triethylamine and triethanolamine; ammonium hydroxide salt such as tetramethylammonium hydroxide, benzyltrimethylammonium hydroxide, dodecyltrimethylammonium hydroxide, tetradecyltrimethylammonium hydroxide, hexadecyltrimethylammonium hydroxide, octadecyltrimethylammonium hydroxide, tetraethylammonium hydroxide, tetrapropylammonium hydroxide and tetrabutylammonium hydroxide; alkali metal hydroxide or alkaline earth metal hydroxide such as sodium hydroxide, potassium hydroxide, calcium hydroxide and barium hydroxide. Further, an anion exchange resin which has polystyrene skelton coating a substituent having a quarternary ammonium ion, tertiary amine, secondary amine or primary amine. The basic substance may be preferably amonia or organic amine. The basic substance may be used singly or as admixture of two or more thereof. The amount of the basic substance may be preferably 0.01 to 10 moles, more preferably 0.1 to 1 mole based on 1 mole of the silane compound.

In the second polymerization, the reaction takes place in a solution containing water and solvent such as alcohol. The amount of water used here may be 1 to 500, more preferably 10 to 200 times the weight of silane compound which is the raw material. The solvent that is present with water may be any solvent which can be mixed with water. The solvent may include methanol, ethanol, propanol, isopropyl alcohol, tert-butyl alcohol, propylene glycol monomethyl ether, propylene glycol monopropyl ether and acetone. The amount of the solvent may be 1 to 1000, more preferably 20 to 300 times the weight of the raw material silane compound.

The polymer solution thus prepared may be concentrated by solvent evaporation under the reduced pressure. Solvent which is suitable for the coating device used for the production of the semiconductor device is added to the concentrated solution. Thus, solvent exchange may be carried out to produce a coating liquid. The solvent to be added may be any solvent in which the polymer can be dissolved. The solvent may include alcohol such as n-propyl alcohol, i-propyl alcohol, n-butyl alcohol, sec-butyl alcohol, i-butyl alcohol, t-butyl alcohol, n-pentyl alcohol, i-pentyl alcohol, 2-methylbutanol, sec-pentyl alcohol, t-pentyl alcohol, 3-methoxybutanol, n-hexyl alcohol, 2-methylpentanol, sec-hexyl alcohol, 2-ethylbutanol, propylene glycol monomethyl ether, propylene glycol monoethyl ether, propylene glycol monopropyl ether, diethylene glycol monomethyl ether, diethylene glycol monoethyl ether, diethylene glycol monopropyl ether, dipropylene glycol monomethyl ether, dipropylene glycol monoethyl ether and dipropylene glycol monopropyl ether; ketone such as acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, cyclohexanone, 2-hexanone, methylcyclohexanone, 2,4-pentanedione, acetonylacetone, acetylacetone, 2,4-hexanedione, 2,4-heptanedione, 3,5-heptanedione, 2,4-octanedione and 2,4-nonanedione; diethylcarbonate, ethylene carbonate, propylene carbonate, diethyl carbonate, ethyl acetate, γ-butyrolactone, γ-valerolactone, n-propyl acetate, i-propyl acetate, n-butyl acetate, i-butyl acetate, sec-butyl acetate, t-butyl acetate, n-pentyl acetate, i-pentyl acetate, sec-pentyl acetate, 3-methoxybutyl acetate, 2-ethylbutyl acetate, 2-ethylhexyl acetate, cyclohexyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, glycol diacetate, methoxytriglycol acetate, ethyl propionate, n-butyl propionate, diethyl oxalate, di-n-butyl oxalate, methyl lactate, ethyl lactate, n-propyl lactate, n-butyl lactate, diethyl malonate, dimethyl phthalate, N-ethylformamide, N,N-dimethylformamide, N,N-dimethylacetamide, N-methylpyrrolidone, N-formylmorpholine, n-formylpiperidine, n-formylpyrrolidine, n-acetylmorpholine, and n-acetylpiperidine. The solvent may be used singly or as admixture of two or more thereof.

Although the degree of dilution may depend on the viscosity and intended film thickness, the solvent may be typically added so as to be contained in an amount of 50 to 95 wt %.

The hydrolysis and condensation reactions of the silane compound may take place in the same conditions as conventional hydrolysis and condensation reactions. The reaction temperature may be typically from 0° C. to the boiling point of alcohol generated in the hydrolysis and condensation reactions. The preferable reaction temperature may be from room temperature to 60° C. Although the reaction time is not particularly limited, it may be typically from 10 minutes to 18 hours, more preferably 30 minutes to 3 hours.

A preferable weight-average molecular weight of the polymer obtained by the reaction of the silane compound represented by the Formula (1) or (2) may be 500 to 1,000,000, using a gel permeation chromatography (GPC) based polyethylene.

The polymer solution prepared in this manner may be used as it is or together with a small amount of the other component such as oxide of titanium, oxide of aluminum and oxide of zirconium. The other component may be preferably added in an amount of 0 to 20% by weight based on the weight of the silane compound of Formula (1) or (2) which is the main component.

The composition for forming porous film of the invention can be used as a coating liquid. For example, controlling the concentration of the solute and applying a spin coating with an appropriate frequency of rotations, the film having desirable thickness can be obtained. The actual film having typical thickness of about 0.1 to 2 μm may be formed and will be dried in a subsequent drying step for removing the solvent. The coating method may not be limited to spin coating and may include scan coating, dip coating and bar coating.

The film thus formed may be typically subjected to a drying step (which is usually referred to as pre-bake in the semiconductor process) in which the film is heated at 60 to 120° C. for about 30 seconds to 3 minutes so as to remove the solvent and cure (harden) the film. The heating may be usually done in an air atmosphere, but it can also be done in an inert gas such as nitrogen or argon, or in an oxygen-containing nitrogen atmosphere.

Thin film thus formed may be subjected to the step for forming pores. That is, the thermal treatment at high temperature can produce porous film. The method for heating may not be particularly and may include use of a hot plate or a heating furnace for the wafer processing. The heating temperature may be preferably 150 to 450° C. and the heating time may be preferably 1 minute to 3 hours. The heating can be done in an air atmosphere, or in an inert gas such as nitrogen or argon, in an inert gas containing a reactive gas such as oxygen or fluorine, in a vacuum, or in a combination thereof for multi-heating. Also, the method of heating these is also effective during other stages.

The film which has been subjected to the thermal treatment can have a large specific surface area such as typical value of 500 to 1,000 m²/g measured with Shimazu Tristar 3000) using the BET method, which assesses the absorption of the nitrogen gas. Consequently, the film having very low dielectric constant can be obtained. The porous film of the invention may have dielectric constant of 1.9 to 3.0 measured using the automatic Mercury Probe Method.

Moreover, the porous film obtained may have extremely narrow pore distribution wherein the pore diameters are in the range of 1 to 3 nm and the pores having the diameter of more than 3 nm are hardly present. It is confirmed by the BET surface area measurement using the gas absorption.

Since the film obtained has uniformly distributed fine pores, it has high mechanical strength with minimal deterioration despite the high content of pores. The mechanical strength may be evaluated in various methods. For example, according to the measurement of the nanoindentation, the hardness can be typically 0.1 to 1.0 GPa and the modulus can be about 2.0 to 10 GPa. This indicates that the obtained film has much higher mechanical strength than the porous material in which the pores has been generated by adding a thermally decomposable polymer to silicone resin and removing the polymer by heating. It is because the later can only exhibit hardness of 0.05 to 2 GPa and modulus of about 1.0 to 4.6 GPa.

The porous film of the present invention is particularly preferable as the interlevel insulator film of the interconnections in a semiconductor integrated circuit. The semiconductor device is required to reduce interconnection capacitance in order to prevent interconnection delay when highly integrated. Various means have been developed to achieve this, and one of them is to reduce the relative permittivity of the interlevel insulator film disposed between metal interconnections. When an interlevel insulator film is prepared by using the composition for forming a porous film of the present invention, the semiconductor device can be downsized and faster and consume less power.

However, there is a problem that when a porous film is prepared by introducing pores in the film so as to lower the dielectric constant, the mechanical strength of the film decreases as the density of the material composing the film decreases. The decrease in mechanical strength not only affects the strength of the semiconductor device itself but also causes exfoliation due to insufficient strength in a chemical mechanical polishing process, which is generally used in the fabrication process. Particularly, when used as the interlevel insulator film of a semiconductor, the porous film of the invention having high mechanical strength despite the porosity prevents such exfoliation, thereby greatly improving reliability of the produced semiconductor device.

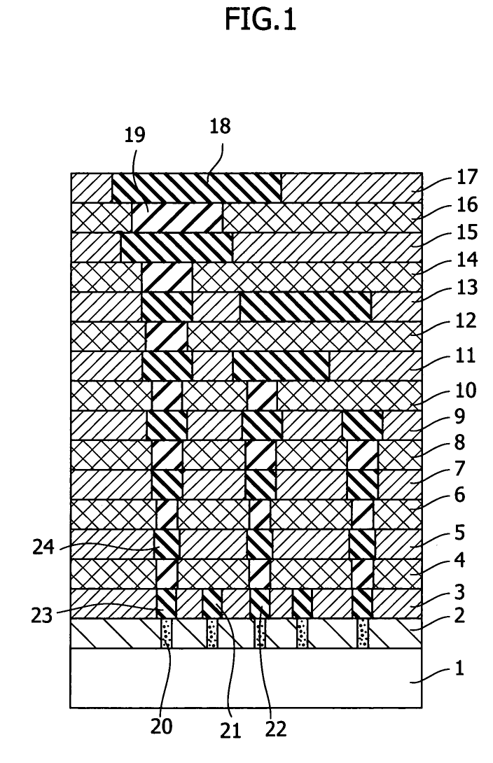

The embodiments of the semiconductor device of the present invention will be described below. FIG. 1 shows a schematic cross-sectional view of an example of the semiconductor device of the present invention.

In FIG. 1, the substrate 1 is an Si semiconductor substrate such as an Si substrate or an SOI (Si-on-insulator) substrate; however, it can be a compound semiconductor substrate such as SiGe or GaAs. The interlevel insulator films include the interlevel insulator film 2 of the contact layer; the interlevel insulator films 3, 5, 7, 9, 11, 13, 15, and 17 of the interconnection layers; and the interlevel insulator films 4, 6, 8, 10, 12, 14, and 16 of the via layers. The interconnection layers corresponding to the lowermost interlevel insulator film 3 through the uppermost insulator film 17 are abbreviated as M1, M2, M3, M4, M5, M6, M7, and M8, respectively. The via layers corresponding to the lowermost interlevel insulator film 4 through the uppermost insulator film 16 are abbreviated as V1, V2, V3, V4, V5, V6, and V7, respectively. Although some of the metal interconnections are referred to with the numbers 18 and 21 to 24, the other regions with the same pattern not labeled with numbers indicate metal interconnections. The via plug 19 is made from a metal. In the case of copper interconnection, copper is generally used. The regions having the same pattern as the via plug 19 represent via plugs although they are not labeled with numbers in the drawing. The contact plug 20 is connected to the gate of the transistor (not illustrated) formed on the top surface of the substrate 1 or to the substrate. Thus, the interconnection layers and the via layers are alternately stacked, and multilayer interconnections generally indicate M1 and regions higher than M1. In general, M1 to M3 are called local interconnections, M4 and M5 are called intermediate interconnections or semi-global interconnections, and M6 to M8 are called global interconnections.

In the semiconductor device of the present invention, the porous film of the present invention is used as one or more of the interlevel insulator films 3, 5, 7, 9, 11, 13, 15, and 17 of the interconnection layers or the insulator films 4, 6, 8, 10, 12, 14, and 16 of the via layers.

For example, when the porous film of the present invention is used for the interlevel insulator film 3 of the interconnection layer (M1), the interconnection capacitance between the metal interconnection 21 and the metal interconnection 22 can be greatly reduced. When the porous film of the present invention is used for the interlevel insulator film 4 of the via layer (V1), the interconnection capacitance between the metal interconnection 23 and the metal interconnection 24 can be greatly reduced. Using the porous film with a low relative permittivity of the present invention as an interconnection layer can greatly reduce the metal interconnection capacitance in the same layer. On the other hand, using the porous film with a low relative permittivity of the present invention as a via layer can greatly reduce the capacitance between the upper and lower metal interconnection layers.

Therefore, using the porous film of the present invention for all of the interconnection layers and the via layers can greatly reduce the parasitic capacitance of the interconnections. Hence, the use of the porous film of the present invention as insulator films of the interconnections prevents a conventional problem, that is, an increase in the dielectric constant resulting from the porous film absorbing humidity while multilayered interconnections are formed by stacking porous films. As a result, the semiconductor device can perform high-speed and low-power operations. The porous film of the present invention enables a semiconductor device to have higher mechanical strength by its high mechanical strength, thereby greatly improving the yield of the fabrication and the reliability of the semiconductor device.

The invention will be described specifically through the following examples, but is not limited to them.

### EXAMPLE 1

A mixture of 30 g (0.22 mol) of methyltrimethoxysilane, 50 g (0.24 mol) of tetraethoxysilane and 14.6 g (0.81 mol) of water was stirred at room temperature and 0.2 ml of 1 N hydrochloric acid was added thereto all at once. After a few minutes, the reaction solution exhibited exothermicity and became homogeneous. The further stirring at room temperature for 1 hour produced a slightly viscous solution. According to the analysis with gel permeation chromatography using tetrahydrofuran as a moving bed, the siloxane had weight-average molecular weight of 1,560 and number-average molecular weight of 1,010 based on polystyrene.

The solution was added all at once to a 60° C. solution of 640 g of water, 1200 g of ethanol and 10 g of an aqueous 28% by weight ammonia solution. The resulting reaction solution was heated with stirring for further 3 hours. After the reaction was over, 400 g of propylene glycol monopropyl ether was added thereto. The solvent evaporation under reduced pressure produced 400 g of colorless coating liquid.

This solution was analyzed in the same manner as before with gel permeation chromatography using tetrahydrofuran as a moving bed, weight-average molecular weight of 115,000.

This solution was applied on an 8″ wafer with a spin coater at 2,000 rpm for one minute, and heated on a hot plate at 100° C. for 1 minute to produce the film having thickness of 430 nm.

The film was heated at 200° C. for a further minute. Then it was heated at 400° C. for 1 hour in a clean oven in a nitrogen atmosphere to produce the film having thickness of 427 nm. The dielectric constant of the film was 2.32 using the CV method with an automatic mercury probe. The measurement of the film based on the absorption of nitrogen gas confirmed that specific surface area was 850 m²/g, a center value of the pore diameters was 2.0 nm and substantially no pores having the diameter of more than 3.0 nm were present. The modulus of the film was 5.5 GPa with a nanoindentar.

### EXAMPLE 2

A mixture of 30 g (0.22 mol) of methyltrimethoxysilane, 50 g (0.24 mol) of tetraethoxysilane and 14.6 g (0.81 mol) of water was stirred at room temperature and 10 g of Amberlite (trademark) 120Plus (H⁺ type) was added thereto all at once. After a few minutes, the reaction solution exhibited exothermicity and became homogeneous. The further stirring at room temperature for 3 hours produced a slightly viscous solution. According to the analysis with gel permeation chromatography using tetrahydrofuran as a moving bed, the siloxane had weight-average molecular weight of 2,150 and number-average molecular weight of 1,250 based on polystyrene.

The solution was added all at once to a 60° C. solution of 640 g of water, 1200 g of ethanol and 10 g of an aqueous 28% by weight ammonia solution. The resulting reaction solution was heated with stirring for further 3 hours. After the reaction was over, 400 g of propylene glycol monopropyl ether was added thereto. Removal of Amberlite 120Plus (H⁺ type) and the solvent evaporation under reduced pressure produced 400 g of colorless coating liquid.

This solution was analyzed in the same manner as before with gel permeation chromatography using tetrahydrofuran as a moving bed, weight-average molecular weight of 145,000.

This solution was applied on an 8″ wafer with a spin coater at 2,000 rpm for one minute, and heated on a hot plate at 100° C. for 1 minute to produce the film having thickness of 483 nm.

The film was heated at 200° C. for further one minute. Then it was heated at 400° C. for 1 hour in a clean oven in a nitrogen atmosphere to produce the film having thickness of 480 nm. The dielectric constant of the film was 2.21 using the CV method with an automatic mercury probe. The modulus of the film was 4.5 GPa with a nanoindentar.

### EXAMPLE 3

A mixture of 30 g (0.22 mol) of methyltrimethoxysilane, 50 g (0.24 mol) of tetraethoxysilane and 14.6 g (0.81 mol) of water was stirred at room temperature and 10 g of Amberlite (trademark) 120Plus (H⁺ type) was added thereto all at once. After a few minutes, the reaction solution exhibited exothermicity and became homogeneous. The further stirring at room temperature for 3 hours produced a slightly viscous solution. According to the analysis with gel permeation chromatography using tetrahydrofuran as a moving bed, the siloxane had weight-average molecular weight of 2,150 and number-average molecular weight of 1,250 based on polystyrene.

The solution was added all at once to a 60° C. solution of 640 g of water, 1200 g of ethanol and 7 g of an aqueous 40% by weight methylamine solution. The resulting reaction solution was heated with stirring for further 3 hours. After the reaction was over, 400 g of propylene glycol monopropyl ether was added thereto. Removal of Amberlite 120Plus (H⁺ type) and the solvent evaporation under reduced pressure produced 400 g of colorless coating liquid.

This solution was analyzed in the same manner as before with gel permeation chromatography using tetrahydrofuran as a moving bed, weight-average molecular weight of 120,000.

This solution was applied on an 8″ wafer with a spin coater at 2,000 rpm for one minute, and heated on a hot plate at 100° C. for 1 minute to produce the film having thickness of 441 nm.

The film was heated at 200° C. for further one minute. Then it was heated at 400° C. for 1 hour in a clean oven in a nitrogen atmosphere to produce the film having thickness of 421 nm. The dielectric constant of the film was 2.32 using the CV method with an automatic mercury probe. The modulus of the film was 6.5 GPa with a nanoindentar.

### EXAMPLE 4

A mixture of 30 g (0.22 mol) of methyltrimethoxysilane, 40 g (0.192 mol) of tetraethoxysilane, 10 g (0.037 mol) of 1,2-bistrimethoxysilylethane and 14.9 g (0.825 mol) of water was stirred at room temperature and 10 g of Amberlite (trademark) 120Plus (H⁺ type) was added thereto all at once. After a few minutes, the reaction solution exhibited exothermicity and became homogeneous. The further stirring at room temperature for 3 hours produced a slightly viscous solution. According to the analysis with gel permeation chromatography using tetrahydrofuran as a moving bed, the siloxane had weight-average molecular weight of 2,400 and number-average molecular weight of 1,200 based on polystyrene.

The solution was added all at once to a 60° C. solution of 640 g of water, 1200 g of ethanol and 7 g of an aqueous 40% by weight methylamine solution. The resulting reaction solution was heated with stirring for further 3 hours. After the reaction was over, 400 g of propylene glycol monopropyl ether was added thereto. Removal of Amberlite 120Plus (H⁺ tpe) and the solvent evaporation under reduced pressure produced 400 g of colorless coating liquid.

This solution was analyzed in the same manner as before with gel permeation chromatography using tetrahydrofuran as a moving bed, weight-average molecular weight of 168,000.

This solution was applied on an 8″ wafer with a spin coater at 2,000 rpm for one minute, and heated on a hot plate at 100° C. for 1 minute to produce the film having thickness of 511 nm.

The film was heated at 200° C. for further one minute. Then it was heated at 400° C. for 1 hour in a clean oven in a nitrogen atmosphere to produce the film having thickness of 492 nm. The dielectric constant of the film was 2.11 using the CV method with an automatic mercury probe. The modulus of the film was 4.2 GPa with a nanoindentar.

### COMPARATIVE EXAMPLE 1

The 30 g (0.22 mol) of methyltrimethoxysilane and 40 g (0.26 mol) of tetramethoxysilane were added dropwise at 25° C. for 5 minutes to a mixture of 640 g of water, 1200 g of ethanol and 10 g of an aqueous 28 wt % ammonia solution, and subsequently stirred at 80° C. for 6 hours. Then, 400 g of propylene glycol monopropyl ether was added thereto. The solvent evaporation under reduced pressure produced 390 g of colorless coating liquid.

This solution was analyzed in the same manner as before with gel permeation chromatography using tetrahydrofuran as a moving bed, weight-average molecular weight of 465,000.

This solution was applied on an 8″ wafer with a spin coater at 2,000 rpm for one minute, and heated on a hot plate at 100° C. for 1 minute to produce the film having thickness of 550 nm.

The film was heated at 200° C. for further one minute. Then it was heated at 400° C. for 1 hour in a clean oven in a nitrogen atmosphere to produce the film having thickness of 545 nm. The dielectric constant of the film was 2.17 using the CV method with an automatic mercury probe. The modulus of the film was 1.15 GPa with a nanoindentar.

### COMPARATIVE EXAMPLE 2

The 30 g (0.22 mol) of methyltrimethoxysilane and 40 g (0.26 mol) of tetramethoxysilane were added dropwise at 25° C. for 5 minutes to a mixture of 640 g of water, 1200 g of ethanol and 10 g of an aqueous 28 wt % ammonia solution, and subsequently stirred at 60° C. for 6 hours. Then, 400 g of propylene glycol monopropyl ether was added thereto. The solvent evaporation under reduced pressure produced 470 g of colorless coating liquid.

This solution was analyzed in the same manner as before with gel permeation chromatography using tetrahydrofuran as a moving bed, weight-average molecular weight of 136,000.

This solution was applied on an 8″ wafer with a spin coater at 2,000 rpm for one minute, and heated on a hot plate at 100° C. for 1 minute to produce the film having thickness of 550 nm.

The film was heated at 200° C. for further one minute. Then it was heated at 400° C. for 1 hour in a clean oven in a nitrogen atmosphere to produce the film having thickness of 545 nm. The dielectric constant of the film was 3.53 using the CV method with an automatic mercury probe. The modulus of the film was 6.96 GPa with a nanoindentar.

TABLE 1

| | weight- | | |
|---|---|---|---|
| | average | | |
| | molecular | dielectric | modulus |
| | weight | constant | (GPa) |
| Example 1 | 115,000 | 2.32 | 5.5 |
| Example 2 | 145,000 | 2.21 | 4.5 |
| Example 3 | 120,000 | 2.32 | 6.5 |
| Example 4 | 168,000 | 2.11 | 4.2 |
| Comp. Ex. 1 | 465,000 | 2.17 | 1.15 |
| Comp. Ex. 2 | 136,000 | 3.53 | 6.96 |

1. A composition for forming porous film comprising a polymer solution produced by hydrolysis and condensation of a reaction solution in the presence of a basic substance as catalyst and wherein the reaction solution has been produced by hydrolysis and condensation, in the presence of an acidic substance as catalyst, of one or more silane compounds selected from the group consisting of the compounds represented by Formulae (1) and (2):
(R)ₐSi(OR¹)₄₋ₐ (1)
(R²O)_{b}(R³)_{4-b}Si—R⁴—Si(OR⁵)c(R⁶)_{4-c} (2)
wherein, in Formula (1), R represents a straight-chain or branched alkyl group having 1 to 8 carbons or an aryl group in which each group may have a substituent, and when two or more R's are present, the R's may be the same or different; R¹ represents an alkyl group having 1 to 4 carbons, and when two or more R's are present, the R's may be the same or different; “a” represents an integer of from 0 to 3; and
in Formula (2), R² and R⁵ each independently represents an alkyl group having 1 to 4 carbons; R³ and R⁶ each independently represents a straight-chain or branched alkyl group having 1 to 8 carbons or an aryl group; b and c each represents an integer of 0 to 3; and R⁴ is selected from the group consisting of an oxygen atom; a phenylene group, —(CH₂)_{d}— wherein d is a integer of from 1 to 6and, —{Si(R⁷)(R⁸)O}ₑ— wherein R⁷ and R⁸ each independently represents an alkyl group having 1 to 6 carbons or an aryl group, and e is an integer of from 1 to 20.

2. The composition for forming porous film according to claim 1 comprising an organic solvent.

3. The composition for forming porous film according to claim 1 wherein said acidic substance is a compound having a substituent which contains a functional group which is dissociated to generate a proton.

4. The composition for forming porous film according to claim 3 wherein said functional group which can generate a proton is a sulfo group or a carboxyl group.

5. The composition for forming porous film according to claim 1 wherein said basic substance is ammonia or organic amine.

6. A method for producing porous film comprising steps of applying said composition according to claim 1 on a substrate, drying, and heating for forming pores.

7. Porous film prepared from said composition according to claim 1.

8. Interlevel insulator film prepared from said composition according to claim 1.

9. A method for producing a composition for forming porous film comprising:
preparing a reaction solution by hydrolysis and condensation, in the presence of acidic substance as catalyst, one or more silane compounds represented by Formulae (1) and (2):
(R)ₐSi(OR¹)₄₋ₐ (1)
(R²O)_{b}(R³)_{4-b}Si—R⁴—Si(OR⁵)c(R⁶)_{4-c} (2)
wherein, in Formula (1), R represents a straight-chain or branched alkyl group having 1 to 8 carbons or an aryl group wherein each group may have a substituent, and when two or more R's are present, the R's may be the same or different; R¹ represents an alkyl group having 1 to 4 carbons, and when two or more R¹'s are present, the R¹'s may be the same or different; “a” represents an integer of from 0 to 3; and
in Formula (2), R² and R⁵ each independently represents an alkyl group having 1 to 4 carbons; R³ and R⁶ each independently represents a straight-chain or branched alkyl group having 1 to 8 carbons or an aryl group; b and c each represents an integer of 0 to 3; and R⁴ is selected from the group consisting of an oxygen atom; a phenylene group, —(CH₂)_{d}— wherein d is a integer of from 1 to 6 and, —{Si(R⁷)(R⁸)O}ₑ— wherein R⁷ and R⁸ each independently represents an alkyl group having 1 to 6 carbons or an aryl group, and e is an integer of from 1 to 20; and
subjecting the reaction solution to hydrolysis and condensation in the presence of a basic substance as a catalyst.

10. A semiconductor device having an internal porous film formed from a composition comprising a polymer solution obtained by hydrolysis and condensation of a reaction solution in the presence of a basic substance as catalysts, wherein the reaction solution has been produced by hydrolysis and condensation, in the presence of an acidic substance as catalyst, of one or more silane compounds selected from the group consisting of the compounds represented by Formulae (1) and (2):
(R)ₐSi(OR¹)₄₋ₐ (1)
(R²O)_{b}(R³)_{4-b}Si—R⁴—Si(OR⁵)c(R⁶)_{4-c} (2)
wherein, in Formula (1), R represents a straight-chain or branched alkyl group having 1 to 8 carbons or an aryl group in which each group may have a substituent, and when two or more R's are present, the R's may be the same or different; R¹ represents an alkyl group having 1 to 4 carbons, and when two or more R¹'s are present, the R¹'s may be the same or different; “a” represents an integer of from 0 to 3; and
in Formula (2), R² and R⁵ each independently represents an alkyl group having 1 to 4 carbons; R³ and R⁶ each independently represents a straight-chain or branched alkyl group having 1 to 8 carbons or an aryl group; b and c each represents an integer of 0 to 3; and R⁴ is selected from the group consisting of an oxygen atom; a phenylene group, —(CH₂)_{d}— wherein d is a integer of from 1 to 6 and, —{Si(R⁷)(R⁸)O}ₑ—wherein R⁷ and R⁸ each independently represents an alkyl group having 1 to 6 carbons or an aryl group, and e is an integer of from 1 to 20.

11. The semiconductor device according to claim 10 wherein said composition comprises an organic solvent.

12. The semiconductor device according to claim 10 wherein said acid substance is a compound having a substituent which contains a functional group which is dissociated in said reaction solution to generate a proton.

13. The semiconductor device according to claim 12 wherein said functional group which can generate a proton is a sulfo group or a carboxyl group.

14. The semiconductor device according to claim 10 wherein said basic substance is ammonia or organic amine.

15. The semiconductor device according to claim 10 wherein said porous film is between metal interconnections in a single layer of multi-level interconnects or is between upper and lower metal interconnection layers.
